(19) United States
(12) Patent Application Publication
(10) Pub. No.: US 2022/0336203 A1
(43) Pub. Date: Oct. 20, 2022

(54) FABRICATION METHOD OF SEMICONDUCTOR SUBSTRATE

(71) Applicant: GlobalWafers Co., Ltd., Hsinchu (TW)

(72) Inventors: Chin Chen Chiu, Hsinchu (TW); Hao-Wei Peng, Hsinchu (TW)

(73) Assignee: GlobalWafers Co., Ltd., Hsinchu (TW)

(21) Appl. No.: 17/714,150

(22) Filed: Apr. 6, 2022

Related U.S. Application Data
(60) Provisional application No. 63/175,058, filed on Apr. 15, 2021.

(51) Int. Cl. H01L 21/02

(52) U.S. Cl. CPC H01L 21/02024

(57) ABSTRACT

A fabrication method of a semiconductor substrate includes: performing a chemical mechanical polishing process on a silicon carbide wafer; and performing a heating process on the silicon carbide wafer to remove a naturally formed oxide layer, to remove contaminants, to obtain a scratch-free surface, and to planarize, wherein the heating process includes: heating a chamber of a furnace and the silicon carbide wafer to T degrees Celsius for a time t, and introducing hydrogen, argon, nitrogen, or/and hydrogen chloride into the chamber; and then cooling down the furnace.

### CROSS-REFERENCE TO RELATED APPLICATION

This application claims the priority benefit of U.S. provisional application Ser. No. 63/175,058 filed on Apr. 15, 2021. The entirety of the above-mentioned patent application is hereby incorporated by reference herein and made a part of this specification.

### BACKGROUND

Technical Field

The disclosure relates to a fabrication method of a semiconductor substrate, and in particular relates to a fabrication method of a semiconductor substrate that includes silicon carbide.

Description of Related Art

In the semiconductor industry, a fabrication method of a wafer includes first forming an ingot, and then dicing the ingot to obtain a wafer. Ingots are fabricated, for example, in a high temperature environment. In the fabrication process of some ingots, a seed is placed in a high temperature furnace, the seed contacts a gaseous or liquid raw material, and forms a semiconductor material on the surface of the seed until an ingot with a desired size is obtained. Ingots may consist of different crystalline structures depending on the fabrication methods and the raw materials.

After the ingot growth is completed, the ingot is cooled down to room temperature by furnace cooling or other manners. After the ingot is cooled down, the head and tail ends of the ingot with poor shapes are removed by a dicing machine, and then the ingot is polished to a desired size (for example, 3 inches to 12 inches) with a polishing wheel. In the fabrication process of some ingots, a flat edge or a V-shaped groove is polished on the edge of the ingot. The flat edge or V-shaped groove is suitable for marking the crystallization direction of the ingot. Then, the ingot is diced to obtain multiple wafers.

In some cases, after processing (for example, surface polishing, heating treatment, etc.) the wafer, many unexpected defects appear on the surface of the wafer. The unexpected defects severely affect the process yield of the subsequent epitaxy process. Therefore, a method that can improve the surface quality of the wafer is urgently needed.

### SUMMARY

The disclosure provides a fabrication method of a semiconductor substrate, which can improve the epitaxial quality of a surface of a silicon carbide wafer.

At least one embodiment of the disclosure provides a fabrication method of a semiconductor substrate, including the following steps. A silicon carbide ingot is formed. The silicon carbide ingot is diced to form a silicon carbide wafer. A chemical mechanical polishing process is performed on an upper surface of the silicon carbide wafer, and a metal oxide is formed on the upper surface of the silicon carbide wafer. The silicon carbide wafer is placed into a chamber of a furnace, and a heating process is performed on the silicon carbide wafer. The heating process includes the following steps. The chamber is heated to T degrees Celsius for a time t. During the time t when the temperature of the chamber is T degrees Celsius, hydrogen and an inert gas, such as argon or nitrogen, are continuously introduced into the chamber. The metal oxide is reduced to metal by the hydrogen. During the time t when the temperature of the chamber is T degrees Celsius, from a beginning to a time tl, hydrogen chloride is continuously introduced into the chamber. The time tl is less than the time t. The metal reacts with the hydrogen chloride to form metal chloride and leaves the upper surface of the silicon carbide wafer. A molecular thermal diffusion is induced by the upper surface of the silicon carbide wafer during the heating process. Atoms on the surface of the substrate are rearranged, and defects or dislocations are reduced, while a nanoscale stepped surface is formed. The chamber of the furnace is cooled down.

### BRIEF DESCRIPTION OF THE DRAWING

FIG. 1A to FIG. 1F are cross-sectional schematic views of a fabrication method of a semiconductor substrate according to an embodiment of the disclosure.

FIG. 2 is a temperature graph of performing a heating process on a silicon carbide wafer according to an embodiment of the disclosure.

FIG. 3 is an optical microscope photograph of a silicon carbide wafer according to an embodiment of the disclosure.

FIG. 4 is an atomic force field microscope photograph of a surface of a silicon carbide wafer according to an embodiment of the disclosure.

FIG. 5A is a macroscopic photograph of dendritic defects in a silicon carbide wafer caused by not introducing hydrogen chloride into a chamber.

FIG. 5B is a macroscopic photograph of a silicon carbide wafer formed by introducing hydrogen chloride into a chamber.

DETAILED DESCRIPTION OF DISCLOSED EMBODIMENTS

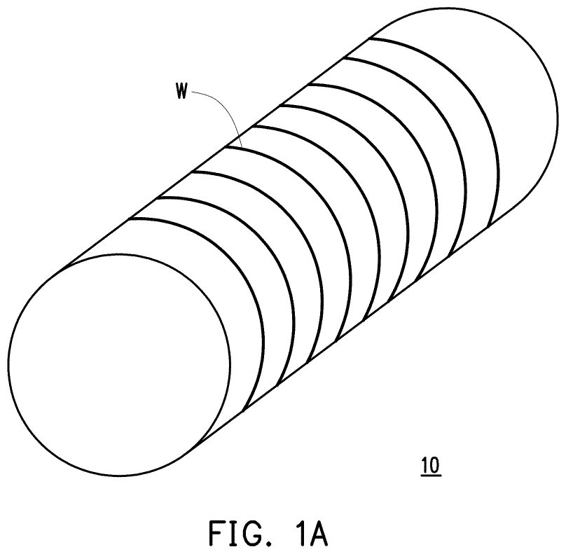

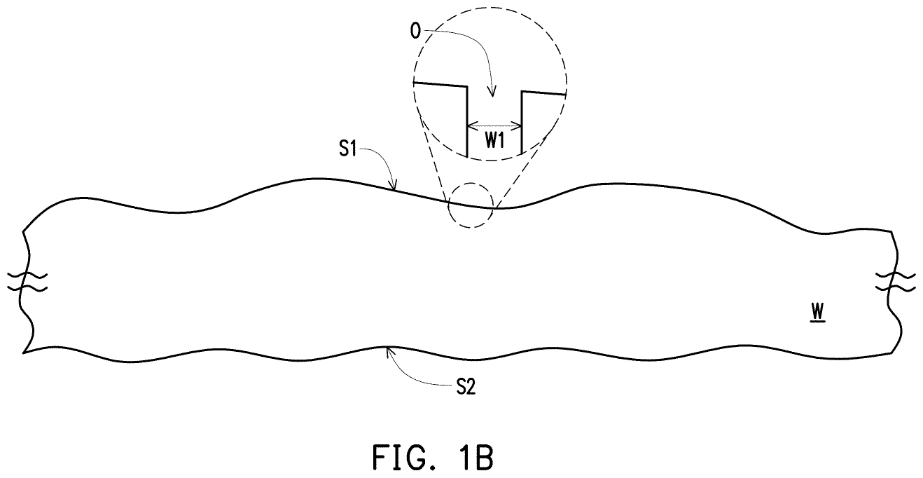

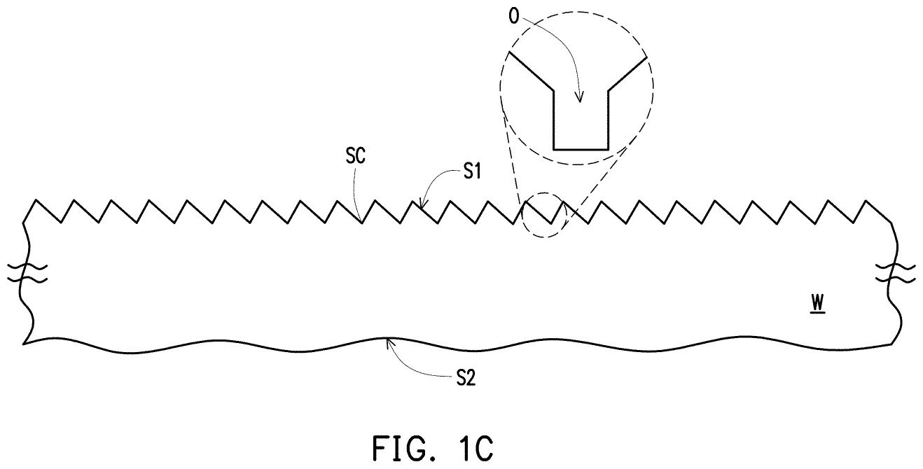

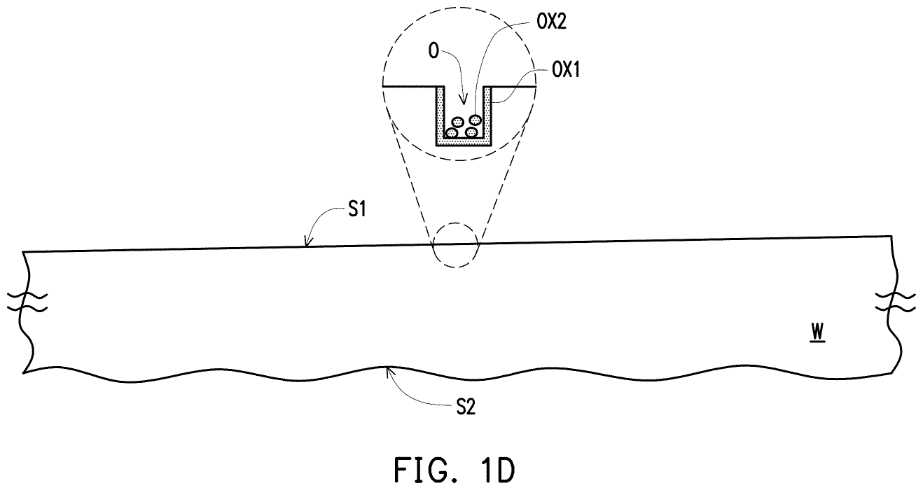

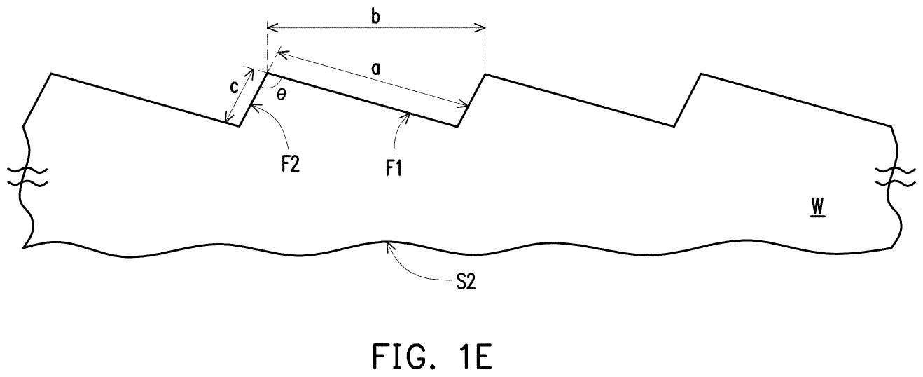

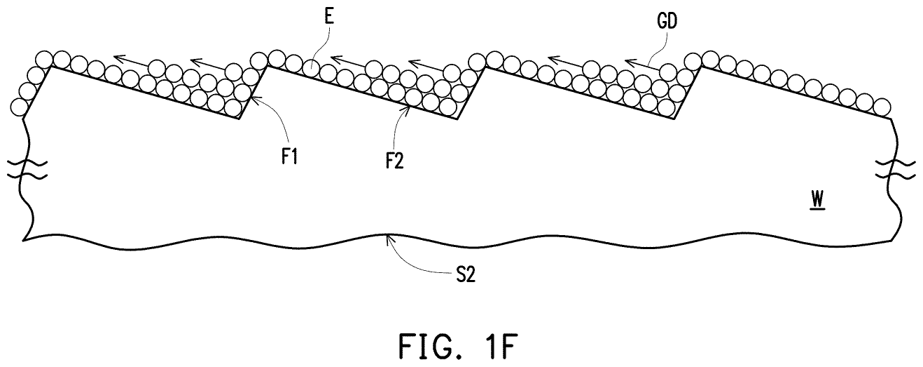

FIG. 1A to FIG. 1F are cross-sectional schematic views of a fabrication method of a semiconductor substrate according to an embodiment of the disclosure.

Referring to FIG. 1A, a silicon carbide ingot 10 is formed, for example, by a physical vapor transport (PVT) process. For example, a seed is placed in a high temperature furnace (such as a high temperature graphite ingot growth furnace), then the high temperature furnace is heated to several thousand degrees Celsius (for example, about 2450 degrees Celsius), and a raw material that includes carbon and silicon elements is gasified. The gas produced after the gasification of the raw material including carbon and silicon elements contacts the seed, and silicon carbide grows on the surface of the seed. The growth of silicon carbide on the surface of the seed is continued until a silicon carbide ingot 10 with a desired size is obtained. The silicon carbide ingot 10 may consist of different crystalline structures depending on the fabrication method and the raw material. For example, the silicon carbide ingot 10 includes 3C-silicon carbide, 4H-silicon carbide, 6H-silicon carbide, and the like. 3C-silicon carbide belongs to the cubic crystal system, while 4H-silicon carbide and 6H-silicon carbide belong to the hexagonal crystal system. In this embodiment, the silicon carbide ingot 10 mainly includes silicon carbide of the hexagonal crystal system.

After the silicon carbide ingot 10 is formed, the silicon carbide ingot 10 is diced to form multiple silicon carbide wafers W. For example, the silicon carbide ingot 10 is repeatedly diced by multiple dicing lines wound on a roller, so that the silicon carbide ingot 10 is diced into tens to hundreds of silicon carbide wafers W. In some embodiments, the silicon carbide ingot 10 is diced with diamond wires (steel wires attached with diamond particles), but the disclosure is not limited thereto. In other embodiments, the silicon carbide ingot 10 is diced with a knife, a laser, a water jet, or other manners.

In some embodiments, before dicing the silicon carbide ingot 10, an edge of the silicon carbide ingot 10 is polished, so that the edge of the silicon carbide ingot 10 relatively flat, but the disclosure is not limited thereto.

In some embodiments, a thickness of the silicon carbide wafer W obtained after dicing the silicon carbide ingot 10 is about several hundreds of micrometers.

Referring to FIG. 1B, an upper surface Si and a lower surface S2 of the silicon carbide wafer W obtained after dicing the silicon carbide ingot 10 is uneven due to insufficient precision of the dicing process. In this embodiment, the upper surface S1 of the silicon carbide ingot 10 is a silicon surface, and the lower surface S2 of the silicon carbide ingot 10 is a carbon surface.

In this embodiment, the surface of the silicon carbide wafer W has holes O. The holes O may appear inside the silicon carbide ingot 10 during the growth process of the silicon carbide ingot 10, and may then be exposed on the surface of the silicon carbide wafer W after the silicon carbide ingot 10 is diced. The holes O may even be micro-cracks, imprints, or scratches and pits induced by a machining process.

A width w1 of the hole O is, for example, several nanometers to tens of micrometers. In some embodiments, a depth of the hole O may be from several nanometers to tens of micrometers.

Referring to FIG. 1C, the upper surface S1 of the silicon carbide ingot 10 is polished by a physical polishing process. For example, the upper surface S1 of the silicon carbide wafer W is polished with an abrasive including diamond particles with an average particle size of about tens of nanometers (for example, 50 nanometers) and a polishing pad.

In this embodiment, the physical polishing process is limited by the size of the diamond particles, and scratches SC are formed on the upper surface S1 of the silicon carbide wafer W. The depth of the scratches SC may be several nanometers to tens of nanometers.

After the physical polishing process is performed on the upper surface S1 of the silicon carbide wafer W, since the overall thickness of the silicon carbide wafer W is reduced, the depth of the holes O on the upper surface Si is also reduced.

Referring to FIG. 1D, a chemical mechanical polishing process is performed on the upper surface S1 of the silicon carbide wafer W, and a metal oxide OX2 is formed on the upper surface S1 of the silicon carbide wafer W.

In this embodiment, performing the chemical mechanical polishing process on the upper surface S1 of the silicon carbide wafer W includes treating the upper surface S1 of the silicon carbide wafer W with potassium permanganate (KMnO₄) and an acid (for example, nitric acid (HNO₃)), so that the metal oxide OX2 (manganese oxide particles) and a silicon oxide film OX1 are formed on the upper surface S1 of the silicon carbide wafer W.

In this embodiment, when the chemical mechanical polishing process is performed on the silicon carbide wafer W, the reaction of Chemical Formula 1 occurs on the upper surface Si of the silicon carbide wafer W. Chemical Formula 1

2H₂O +4KMnO₄→4MnO₂+30₂+4KOH

The acid (for example, nitric acid (HNO₃)) added in the chemical mechanical polishing process neutralizes the potassium hydroxide (KOH) produced by the reaction of Chemical Formula 1, so that the concentration of potassium hydroxide (KOH) is reduced, thereby facilitating the continuation of the reaction, continuously producing solid water-insoluble manganese oxide particles. At the same time, the silicon carbide on the upper surface S1 of the silicon carbide wafer W is oxidized to generate the silicon oxide film OX1 and carbon-including by-products such as carbon dioxide gas and/or carbon monoxide gas. The hardness of the silicon oxide film OX1 is less than that of silicon carbide, so that the silicon oxide film OX1 may be easily removed by other abrasives (for example, manganese oxide particles produced by the reaction of Chemical

Formula 1 or other additional solid particles). For example, the silicon oxide film OX1 is removed by polishing with a polishing pad and manganese oxide particles or other additional solid particles.

In some embodiments, the silicon oxide film OX1 is easier to form on sharp protrusions (with greater surface energy) of a surface, so the sharp protrusions of the surface are removed faster than flat portions of the surface, so that the upper surface S1 of the silicon carbide wafer W becomes flatter.

In this embodiment, the upper surface S1 of the silicon carbide wafer W has holes O, and the silicon oxide film OX1 is formed not only on a surface of the silicon carbide wafer W facing outward, but also on surfaces inside the holes O. The silicon oxide film OX1 located in the hole O is difficult to be removed by other abrasives. In addition, the metal oxide OX2 produced by the reaction of Chemical Formula 1 is also easily accumulated in the hole O.

In some embodiments, the thickness of the silicon oxide film OX1 in the hole O is approximately in nanoscale, and the particle size of the water-insoluble metal oxide OX2 in the hole O is in nanoscale.

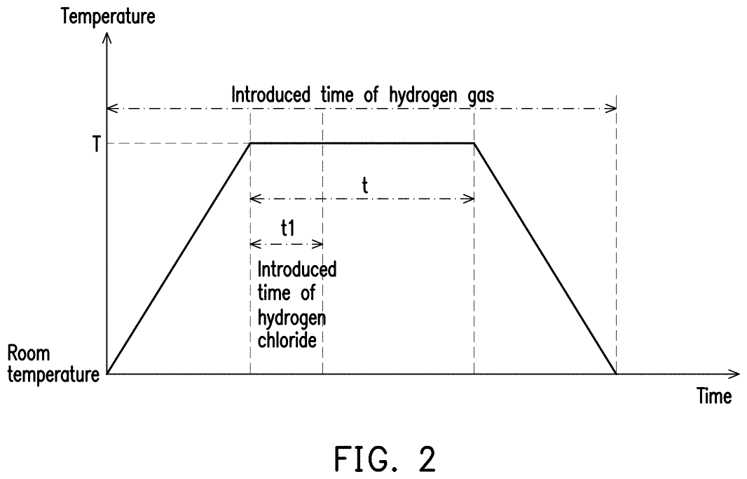

Referring to FIG. 1E and FIG. 2, after the chemical mechanical polishing process is performed on the upper surface S1 of the silicon carbide wafer W, the silicon carbide wafer W is placed in the chamber of the furnace, and a heating process is performed on the silicon carbide wafer W.

The heating process includes heating the chamber to T degrees Celsius in an environment under atmospheric pressure for a time t. During the time t when the temperature of the chamber is T degrees Celsius, hydrogen and an inert gas are continuously introduced into the chamber, and the inert gas is, for example, argon or nitrogen. During the time t when the temperature of the chamber is T degrees Celsius, from the beginning to a time t1, hydrogen chloride is continuously introduced into the chamber, wherein the time t1 is less than the time t. In some embodiments, T degrees Celsius is 1150 degrees Celsius to 1300 degrees Celsius. In some embodiments, the time t is 30 minutes to 120 minutes, and the time t1 is 0 minutes to 30 minutes. In some embodiments, hydrogen and argon are introduced into the chamber, the flow rate of the nitrogen is 0.5 SLPM to 150 SLPM, and the flow rate of the hydrogen chloride introduced into the chamber is 0 SLPM to 20 SLPM.

In this embodiment, the introduction of the hydrogen into the chamber facilitates the slippage of dislocations inside the silicon carbide wafer W, and the naturally formed silicon oxide is removed, thereby reducing or even completely removing the scratches from the surface of the silicon carbide wafer W. If hydrogen is not introduced into the chamber, the silicon carbide wafer W needs to be annealed at a higher temperature (for example, a temperature higher than T degrees Celsius) to effectively reduce the dislocation defects of the silicon carbide wafer W. In other words, the introduction of the hydrogen can reduce the annealing temperature of the silicon carbide wafer W, thereby saving the energy cost required for annealing the silicon carbide wafer W. In addition, the metal oxide OX2 that may exist in the hole O of the silicon carbide wafer W is reduced to metal (for example, manganese (Mn)) by the hydrogen.

In this embodiment, the purpose of introducing hydrogen chloride into the chamber is to react the metal (for example, manganese (Mn)) with hydrogen chloride to form metal chloride (for example, manganese chloride (MnCl2)) and leave the upper surface S1 of the silicon carbide wafer W, or the purpose is to remove the metal entrained in the chemical polishing process, and at the same time, the purpose is also to perform a nanoscale chemical etching on the silicon carbide wafer W.

The upper surface S1 of the silicon carbide wafer W forms a nanoscale stepped surface after the heating process. In this embodiment, the stepped surface is the silicon surface of the silicon carbide wafer W. The stepped surface includes multiple steps, and each of the steps includes a first surface F1 and a second surface F2. An included angle θ between the first surface F1 and the second surface F2 is 70 degrees to 110 degrees. In some embodiments, a pitch b between the steps is 21 nm to 60 nm.

In some embodiments, the first surface F1 corresponds to a basal plane (0001) of silicon carbide, and the second surface F2 corresponds to an r-plane, an m-plane, and/or an a-plane. In the same unit area, a surface energy of the second surface F2 is higher than that of the first surface F1. Since the epitaxial layer is easier to grow along a parallel direction GD on the second surface F2 with high surface energy as the starting surface, the second surface F2 facilitates the growth of the epitaxial layer in the subsequent epitaxial process.

In some embodiments, a length a of the first surface F1 is 20 nm to 60 nm, 25 nm to 40 nm, 20 nm to 80 nm, and a length c of the second surface F2 is 8 nm to 20 nm, 8 nm to 16 nm, and 10 nm to 14 nm. In some embodiments, the chamber of the furnace is then cooled down by furnace cooling. In some embodiments, the defect changes in the silicon carbide wafer W are analyzed by a photoluminescence spectrum (PL) or an X-ray, therefore verifying that the defects in the silicon carbide wafer W are significantly reduced after the heating process.

Referring to FIG. 1F, an epitaxial process is performed to form an epitaxial layer E on the first surface F1 and the second surface F2. The material of the epitaxial layer E is, for example, aluminum nitride (AlN) or other suitable semiconductor materials. In some embodiments, the epitaxial process is performed on the silicon carbide wafer W first, and then the silicon carbide wafer W is cooled down. In other words, the epitaxial process may be performed in the chamber used in the heating process, and the temperature at which the epitaxial process is performed may be different from the temperature of the heating process. In other embodiments, the silicon carbide wafer W is cooled down first, and then after the silicon carbide wafer W is transferred to another chamber, the silicon carbide wafer W is heated and the epitaxial process is performed.

Based on the above, in the heating process of the silicon carbide wafer W, the introduction of hydrogen and hydrogen chloride into the chamber facilitates the growth of a low-defect epitaxial layer on the surface of the silicon carbide wafer W.

In some embodiments, in an environment under atmospheric pressure, the silicon carbide wafer W is heated to 1200 degrees Celsius and maintained at such temperature, and the relevant parameters of the hydrogen and hydrogen chloride are adjusted, as shown in Table 1.

TABLE 1

| | | | | Chance | Chance |
|---|---|---|---|---|---|
| | | | | of | of |
| Experimental | Introduced | Introduced | Flow | dendritic | stepped |
| group | gas | time | (SLPM) | defects | surface |
| 1.1 | H₂ | 0~60 minutes | 80 | 100% | 100% |
| 1.2 | H₂ | 0~60 minutes | 80 | 0% | 50% |
| | HC1 | 0~60 minutes | 0.8 | | |
| 1.3 | H₂ | 0~30 minutes | 80 | 100% | 100% |
| 1.4 | H₂ | 0~30 minutes | 80 | 30% | 100% |
| | HC1 | 0~5 minutes | 0.8 | | |
| 2.1 | H₂ | 0~30 minutes | 80 | 100% | 100% |
| 2.2 | H₂ | 0~30 minutes | 80 | 50% | 100% |
| | HC1 | 0~3 minutes | 0.4 | | |
| 2.3 | H₂ | 0~30 minutes | 80 | 100% | 100% |
| | HC1 | 15~20 minutes | 0.8 | | |
| 2.4 | H₂ | 0~30 minutes | 80 | 100% | 50% |
| | HC1 | 25~30 minutes | 0.8 | | |
| 3.1 | H₂ | 0~30 minutes | 40 | 0% | 50% |
| | HC1 | 0~30 minutes | 15 | | |
| 3.2 | H₂ | 0~15 minutes | 40 | 0% | 50% |
| | HC1 | 0~15 minutes | 15 | | |
| 4.1 | H₂ | 0~30 minutes | 40 | 0% | 100% |
| | HC1 | 0~15 minutes | 15 | | |

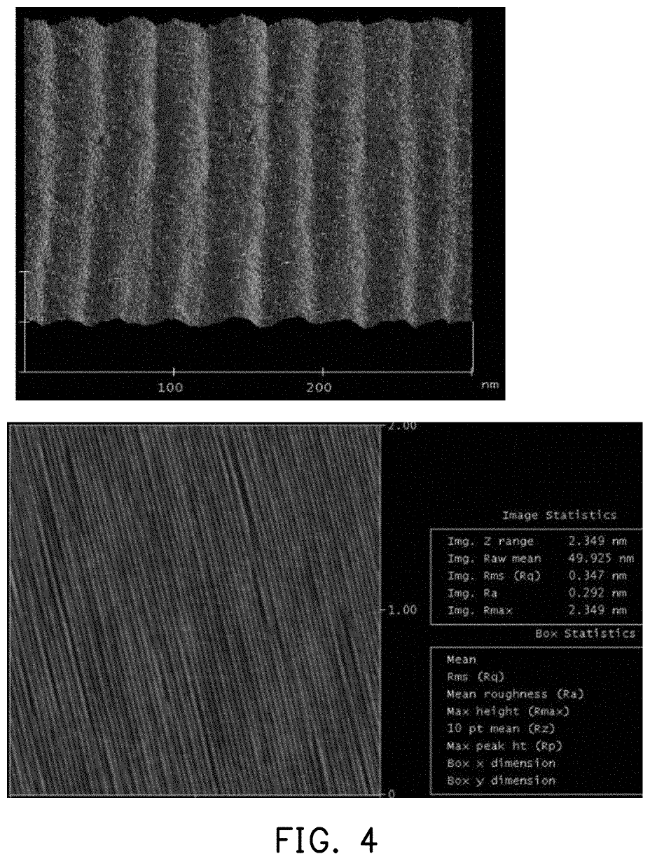

* The presence or absence of dendritic defects is determined by observing with a 100x optical microscope, and 10 observation points at specific positions are taken for each substrate.
* The morphology of the nanoscale stepped surface is determined by observing a 2μm x 2μm image with an atomic force field microscope (AFM), taking the center of the substrate as the observation point (see FIG. 4).

A 50% probability of a stepped surface in Table 1 indicates that the stepped structure is not obvious.

In Table 1, the column “Introduced Time” represents the time after the temperature of the chamber reaches 1200 degrees Celsius. For example, the 0th minute refers to just reaching 1200 degrees Celsius, and the 15th minute refers to the 15th minute after the temperature of the chamber reaches 1200 degrees Celsius. In the embodiment in Table 1, the total time for the chamber to be heated and maintained at 1200 degrees Celsius is the total time for introducing hydrogen recorded in Table 1. However, hydrogen may still be introduced into the chamber while the chamber is being heated (that is, from room temperature to 1200 degrees Celsius) and while the chamber is being cooled downed (that is, from 1200 degrees Celsius to room temperature).

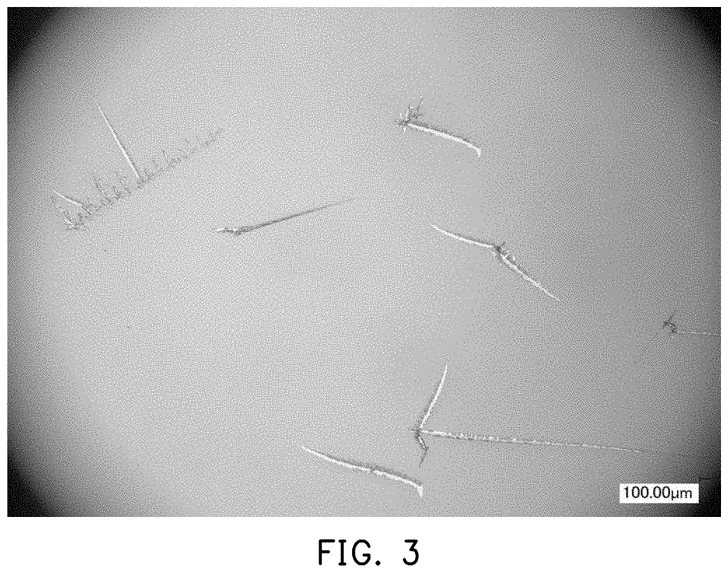

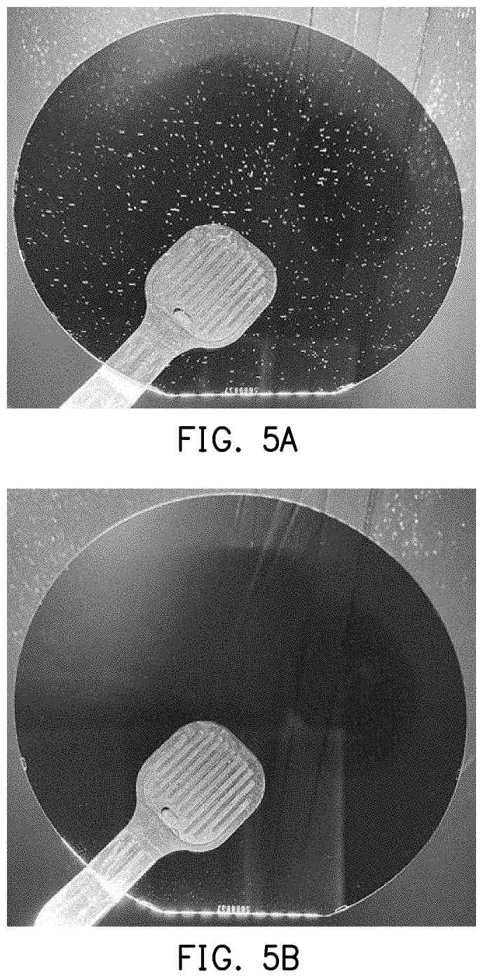

If hydrogen chloride was not introduced into the chamber (for example, Experimental groups 1.1, 1.3, and 2.1) or if hydrogen chloride was introduced into the chamber too late (for example, Experimental groups 2.3 and 2.4), the obtained silicon carbide wafer would have many obvious dendritic defects appearing on the surface, as shown in the optical microscope photograph in FIG. 3. FIG. 4 is a stepped surface observed with an atomic force field microscope. The dendritic defects may be caused by residual manganese on the surface of the silicon carbide wafer, which were not removed by cleaning after polishing. Based on this, introducing hydrogen chloride into the chamber just after heating to a predetermined temperature (for example, Experimental groups 1.2, 1.4, 3.1, 3.2, and 4.1) may facilitate the reduction of dendritic defects on the surface of the silicon carbide wafer. FIG. 5A is a macroscopic photograph of dendritic defects in a silicon carbide wafer caused by not introducing hydrogen chloride into a chamber. Pure hydrogen is introduced into the chamber of the furnace when the heating process is performed on the silicon carbide wafer in FIG. 5A. FIG. 5B is a macroscopic photograph of a silicon carbide wafer formed by introducing hydrogen chloride into a chamber. The introduction of hydrogen chloride greatly reduces the dendritic defects.

What is claimed is:

1. A fabrication method of a semiconductor substrate, comprising:
providing a silicon carbide wafer, the silicon carbide wafer comprising an upper surface and a bottom surface corresponding to the upper surface;
performing a chemical mechanical polishing process on the upper surface of the silicon carbide wafer, and forming a metal oxide on the upper surface of the silicon carbide wafer;
placing the silicon carbide wafer into a chamber of a furnace, and performing a heating process on the silicon carbide wafer, wherein the heating process comprises:
heating the chamber to T degrees Celsius for a time t, wherein:
during the time t when a temperature of the chamber is T degrees Celsius, hydrogen is continuously introduced into the chamber, wherein the metal oxide is reduced to a metal by the hydrogen, during the time t when the temperature of the chamber is T degrees Celsius, from a beginning to a time t1, hydrogen chloride is continuously introduced into the chamber, wherein the time t1 is less than the time t, wherein the metal reacts with the hydrogen chloride to form metal chloride and leaves the upper surface of the silicon carbide wafer, wherein a nanoscale stepped surface is formed on the upper surface of the silicon carbide wafer after the heating process;
and cooling down the chamber.

2. The fabrication method according to claim 1, wherein T degrees Celsius is 1150 degrees Celsius to 1300 degrees Celsius, the time t is 30 minutes to 120 minutes, and the time tl is 0 minutes to 30 minutes.

3. The fabrication method according to claim 1, wherein a flow rate of the hydrogen introduced into the chamber is 0.5 SLPM to 150 SLPM, and a flow rate of the hydrogen chloride introduced into the chamber is 0 SLPM to 20 SLPM.

4. The fabrication method according to claim 1, wherein performing the chemical mechanical polishing process on the upper surface of the silicon carbide wafer comprises:
treating the upper surface of the silicon carbide wafer with potassium permanganate and an acid, so that manganese oxide particles and a silicon oxide film are formed on the upper surface of the silicon carbide wafer, wherein the upper surface of the silicon carbide wafer has holes, the silicon oxide film is formed on surfaces inside the holes, and a portion of the manganese oxide particles are located in the holes.

5. The fabrication method according to claim 1, wherein the stepped surface of the silicon carbide wafer comprises a plurality of steps, and each of the steps comprises a first surface and a second surface, wherein an included angle between the first surface and the second surface is 70 degrees to 110 degrees.

6. The fabrication method according to claim 5, wherein a pitch b between the steps is 21 nm to 60 nm.

7. The fabrication method according to claim 5, wherein in a same unit area, a surface energy of the second surface is higher than a surface energy of the first surface, a length a of the first surface is 20 nm to 60 nm, and a length c of the second surface is 8 nm to 16 nm.

8. The fabrication method according to claim 1, wherein the silicon carbide wafer comprises 6H-SiC, 4H-SiC, or a combination thereof.

9. The fabrication method according to claim 1, wherein the stepped surface is a silicon surface of the silicon carbide wafer.

10. The fabrication method according to claim 1, further comprising:
forming an epitaxial layer on the stepped surface.
